(19) United States
(12) Patent Application Publication
(10) Pub. No.: US 2014/0318593 A1
(43) Pub. Date: Oct. 30, 2014

(54) NANOPARTICLE COMPACT MATERIALS FOR THERMOELECTRIC APPLICATION

(71) Applicants: RESEARCH TRIANGLE INSTITUTE, Reseaxh Triangle Park, NC (US); NORTH CAROLINA STATE UNIVERSITY, Releigh, NC (US)

(72) Inventors: Rama Venkatasubramanian, Cary, NC (US); Judy Stuart, Apex, NC (US); Ryan Wiitala, Morrisville, NC (US); Peter Thomas, Raleigh, NC (US); Carl C. Koch, Raleigh, NC (US); Tsungta Ethan Chan, Raleigh, NC (US)

(73) Assignees: Research Triangle Institute, Research Triangle Park, NC (US); North Carolina State University, Raleigh, NC (US)

(21) Appl. No.: 14/359,817

(22) PCT Filed: Nov. 21, 2012
(86) PCT No.: PCT/US12/66190

§ 371 Date: May 21, 2014

Related U.S. Application Data
(60) Provisional application No. 61/562,229, filed on Nov. 21, 2011.

(51) Int. Cl. H01L 35/16; H01L 35/18; H01L 35/28

(52) U.S. Cl. CPC H01L 35/16; H01L 35/28; H01L 35/18
USPC 136/238; 428/338

(57) ABSTRACT

A thermoelectric composite and a thermoelectric device and a method of making the thermoelectric composite. The thermoelectric composite is a semiconductor material formed from mechanically-alloyed powders of elemental constituents of the semiconductor material to produce nano-particles of the semiconductor material, and compacted to have at least a bifurcated grain structure. The bifurcated grain structure has at least two different grain sizes including small size grains in a range of 2-200 nm and large size grains in a range of 0.5 to 5 microns. The semiconductor material has a figure of merit ZT, defined as a ratio of the product of square of Seebeck coefficient, S², and electrical conductivity σ divided by the thermal conductivity k, which varies from greater than 1 at 300 K to 2.5 at temperatures of 300 to 500K.

### BACKGROUND OF THE INVENTION

This application claims priority under 35 U.S.C. 119(e) of U.S. Ser. No. 61/562,229, filed Nov. 21, 2011, the entire contents of which are incorporated herein by reference.

### STATEMENT REGARDING FEDERALLY SPONSORED RESEARCH OR DEVELOPMENT

This invention was made with government support under U.S. Army Contract W911NF-08-C-0058. The U.S. Government has certain rights in this invention.

### FIELD OF INVENTION

The invention relates to methods and systems for producing micro and nano-sized particles formed of semiconductor compounds, thermoelectric compositions formed of such particles, and methods for their synthesis.

### DISCUSSION OF THE BACKGROUND

Group IV-VI binary semiconductor materials are currently of interest for use in thermoelectric applications, such as power generation and cooling. For example, Bi2Te3-based compounds or PbTe-based compounds can be used in solid-state thermoelectric (TE) cooling and electrical power generation devices. A frequently utilized thermo-electric figure-of-merit of a thermoelectric device is defined as

$$Z = \frac{{S}^{2} σ}{k} ,$$

where S is the Seebeck coefficient, σ is the electrical conductivity, and k is thermal conductivity. In some cases, a dimensionless figure-of-merit (ZT) is employed, where T can be an average temperature of the hot and cold sides of the device. It has also been suggested that nanostructured materials can provide improvements in a thermoelectric figure-of-merit of compositions incorporating these materials.

### SUMMARY OF THE INVENTION

In one embodiment of the invention, there is provided a thermoelectric composite includinga semiconductor material formed from mechanically-alloyed powders of elemental constituents of the semiconductor material to produce nanoparticles of the semiconductor material and compacted to have at least a bifurcated grain structure. The bifurcated grain structure has at least two different grain sizes including small size grains in a range of 2-200 nm and large size grains in a range of 0.5 to 5 microns.

In one embodiment of the invention, there is provided a thermoelectric device having an n-type compacted thermoelectric element having at least a bifurcated grain structure with at least two different grain sizes including small size grains in a range of 2-200 nm and large size grains in a range of 0.5 to 5 microns, a p-type compacted thermoelectric element having at least a bifurcated grain structure with at least two different grain sizes including small size grains in a range of 2-200 nm and large size grains in a range of 0.5 to 5 microns, a bridging plate connecting the n-type compacted thermoelectric element to the p-type compacted thermoelectric element, and a base plate connected respectively to ends of the n-type compacted thermoelectric element to the p-type compacted thermoelectric element.

In one embodiment of the invention, there is provided a method for making a thermoelectric composite. The method provides powders of elemental constituents of a semiconductor material. The method, under a first substantially oxygen free atmosphere, mechanically-alloys powders of elemental constituents into nanometer size powders. The method, under a second substantially oxygen free atmosphere, compacts the nanometer size powders to produce a compact of the semiconductor material which has at least a bifurcated grain structure with at least two different grain sizes including small size grains in a range of 2-200 nm and large size grains in a range of 0.5 to 5 microns. The compacting produces the thermoelectric composite having a figure of merit ZT, defined as a ratio of the product of square of Seebeck coefficient S² and electrical conductivity σ divided by the thermal conductivity k, which is greater than 1.0 at 300 to 500K.

In one embodiment of the invention, there is provided a thermoelectric device having an n-type compacted thermoelectric element having at least a bifurcated grain structure with at least two different grain sizes including small size grains in a range of 2-200 nm and large size grains in a range of 0.5 to 5 microns, a p-type compacted thermoelectric element having at least a bifurcated grain structure with at least two different grain sizes including small size grains in a range of 2-200 nm and large size grains in a range of 0.5 to 5 microns, a bridging plate connecting the n-type compacted thermoelectric element to the p-type compacted thermoelectric element, and a base plate connected respectively to ends of the n-type compacted thermoelectric element to the p-type compacted thermoelectric element.

It is to be understood that both the foregoing general description of the invention and the following detailed description are exemplary, but are not restrictive of the invention.

### BRIEF DESCRIPTION OF THE FIGURES

A more complete appreciation of the invention and many of the attendant advantages thereof will be readily obtained as the same becomes better understood by reference to the following detailed description when considered in connection with the accompanying drawings, wherein:

FIG. 1A is a schematic diagram of a compaction apparatus to compact IV-VI nanostructures generated in accordance with the teachings of the invention;

FIG. 1B is flowchart depicting process steps for making a thermoelectric compact of the invention;

FIGS. 2A-2F are depictions of bright-field TEM micrographs of p-type and n-type bulk consolidated samples of the invention under various magnification levels;

FIGS. 3A-3D are depictions of XRD spectrum (FIG. 3A and FIG. 3C) and transmission electron microscopy (TEM) (FIG. 3B and FIG. 3D) of an n- and a p-type as-milled powders;

FIGS. 4A and 4B are depictions of XRD spectra of consolidated p-type and n-type bulk disks, respectively;

FIGS. 5A-5D are depictions of bright-field TEM micrographs of p-type and n-type bulk samples (conventionally made) under various magnification levels;

FIGS. 6A-6E are graphical depictions of the measured thermal properties of one of the n-type Bi₂Te_{2.7}Se_{0.3} thermoelectric compacts, as a function of temperature;

FIGS. 6F-6J are graphical depictions of the measured thermal properties of one of the p-type Bi₂Te_{2.7}Se_{0.3} thermoelectric compacts, as a function of temperature; and

FIG. 7 is a photographic depiction of a p-n thermoelectric device made with the thermoelectric composite of one embodiment of the invention; amd

FIG. 8 is a schematic depiction of measured heat-to-electric conversion efficiencies of n-p couples from commercial materials compared with the nano-structure compacts of this invention.

### DETAILED DESCRIPTION

There is a need for methods of synthesizing nanostructured semiconductors from Group IV-VI materials. There is also a need for synthetic methods that provide high yields and can be readily implemented. Moreover, there is a need for improved IV-VI micro and nanostructures that would exhibit enhanced thermoelectric properties. Indeed, to make thermoelectric device technology attractive in energy harvesting and power generation, it requires both high performance n- and p-type materials. Nano-engineered structures are expected to reduce phonon thermal conductivity without affecting or enhancing electronic transport for improved thermoelectric figure of merit (ZT) [see for example, ZT enhancement up to 2.4 at ordinary temperatures of 300K in engineered thin-film superlattices, Venkatasubramanian et al., Nature 413, 597-602 (2001)]. This present invention is the first time ZT>2 in nano-bulk materials at ordinary temperatures of around 400K .

In contrast to nano p-type materials, the development of n-type Bi₂Te₃-based materials has not shown significant progress. Conventionally, binary Bi₂Te₃ showed n-type properties and a ZT˜1.18 at 42° C. while a ternary n-type Bi₂Te_{2.7}Se_{0.3} made with nano-sized powder showed peak ZT˜1.04 at 125° C.

In this invention, bulk nano-composites of both n-type Bi₂Te_{2.7}Se_{0.3} and p-type Bi_{0.4}Sb_{1.6}Te₃ alloy materials have been realized with significantly enhanced ZT, almost approaching 2.4, between 25° C. and 125° C. These novel materials have been realized through an optimized high-pressure compaction process (described below) that maintains a high concentration of nanoscale structures. Electron microscopy of these materials of the invention shows a wide distribution of grain sizes with 5-20 nm precipitates dispersed throughout.

In one embodiment of this invention, the nanoscale structuring leads to a significantly increased Seebeck coefficient at increased temperatures and reduced lattice thermal conductivity while maintaining good electrical transport properties. According to one aspect of the invention, the combination of these effects leads to a significantly enhanced ZT in both n- and p-type bulk Bi₂Te₃-based materials, with ZT up to 2.4 at ˜125° C., thus allowing values of ZT>2 barrier in bulk thermoelectric materials to be realized. Incorporation of these nano-materials into heat-to-electric power conversion devices has resulted in a heat-to-electric conversion efficiency of 7.6% compared to ˜5.6% in state-of-the-art devices using non-nano materials, representing about 36% improvement in device efficiency. This demonstrates an important transition of nano-materials to a device technology for wide ranging waste heat recovery for energy efficiency and solar thermal for renewable energy applications.

As noted above, the performance of thermoelectric devices depends on the figure-of-merit (ZT) of the material, (α²T/ρk_{T}), where α, T, ρ, k_{T} are the Seebeck coefficient, absolute temperature, electrical resistivity, and total thermal conductivity, respectively. Commercial thermoelectric devices utilize alloys, typically n-Bi₂(Se_{y}Te_{1-y})₃ (y˜0.05) and p-BiₓSb₂₋ₓTe_{3-y} (x˜0.5, y˜0.12) for temperatures ranging from −25 to 150° C. For certain alloys, the lattice thermal conductivity (k_{L}) can be reduced more strongly than carrier mobility (μ) leading to enhanced ZT. The highest ZT in conventional alloy bulk thermoelectric material at room temperature (RT) is around ˜4 for both n-type and p-type materials. By contrast, this invention realizes a major enhancement in ZT in p-type Bi₂Te₃/Sb₂Te₃ superlattices, realizing values of about 2.4 at RT.

In one embodiment of the invention, the enhancement in ZT occurs by way of a strong reduction in k_{L} (0.25 W/m-K as compared to 1.0 W/m-K in conventional alloys in the typical a-b plane of Bi₂Te₃ materials) along with a mini-band transport across the superlattice interfaces, leading to minimal anisotropy of carrier transport. These phenomena referred to as phonon-blocking, electron-transmitting structures have been replicated in nano-bulk p-type BiₓSb_{2-x‘Te}₃ materials produced by several methods including melt-spun p-type Bi_{0.52}Sb_{1.48}Te₃ compacted by spark plasma sintering (SPS) reaching ZT˜1.56 and a ZT as high as 1.8 in p-type Bi_{0.4}Sb_{1.6}Te₃ nano-composites. From a structural perspective, these materials are composed of nanoscale grains and precipitates, which are purported to reduce k_{L}, while keeping the other parameters of ZT effectively constant.

In contrast to p-type nano-materials, prior to this invention, there had been no significant enhancements in ZT reported for n-type nano-bulk Bi₂Te₃-based materials. Thus, the demonstration of efficient devices utilizing bulk nano-materials, over conventional materials, had not been possible prior to this invention.

In general, this invention provides methods of synthesizing binary and higher order semiconductor nanoparticles, and more particularly method of synthesizing such nanoparticles formed from Group V-VI compounds, especially but not limited to n-type materials.

The terms “nanoparticles” and “nanostructures,” which are employed interchangeably herein, are known in the art. To the extent that any further explanation may be needed, the terms “nanoparticles” and “nanostructures” primarily refer to material structures having sizes, e.g., characterized by their largest dimension, in a range of a few nanometers (nm) to about a few microns, thereby scattering a range of phonon wavelengths to lower lattice thermal conductivity as desired for high-performance thermoelectric materials. Preferably, such nanoparticles have sizes in a range of about 10 nm to about 200 nm (e.g., in a range of about 5 nm to about 100 nm). In applications where highly symmetric structures are generated, the sizes (largest dimensions) can be as large as tens of microns.

In another aspect, the Group V element can be bismuth (Bi) and/or antimony (Sb) in varying concentrations, and the Group VI element can be tellurium (Te) and/or selenium (Se) in varying concentrations. In another aspect, the compacted materials of the invention can include compounds of SiGe, PbTe, PbTeSe, PbTeGeTe, PbTeGeSbTe, and materials known in the art as Half-Heusler compounds made of Zr, Hf, Co, Sn, Sb and Ni. A variety of reagents containing these elements, e.g., salts of these elements, can be utilized in the above synthesis method. Moreover, in one embodiment, particles of these Group V-VI compounds are used as the stock material from which compacts of the thermoelectric materials are fabricated.

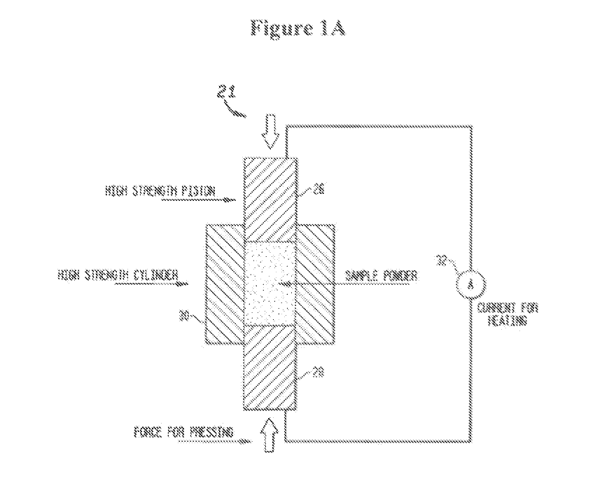

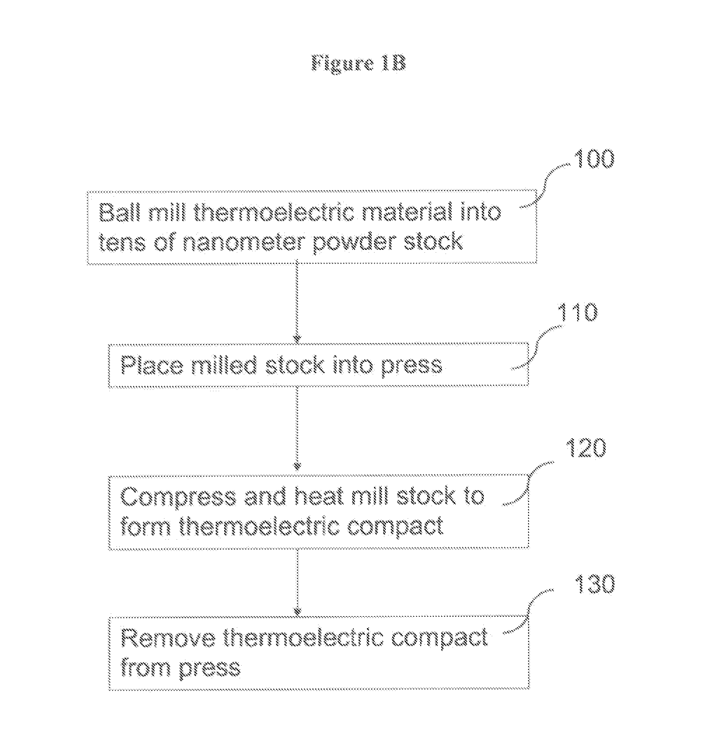

In some embodiments of this invention, previously-synthesized nanoparticles are compacted (densified) at an elevated temperature and under compressive pressure to generate a thermoelectric compact. By way of example, a pressure compaction apparatus 24, shown schematically in FIG. 1, and similar to that described in U.S. Pat. No. 7,255,846, the entire contents of which are incorporated herein by reference, can be employed for this purpose. Accordingly, in one embodiment of the invention, a thermoelectric composite having a Bi₂Te₃₋ₓSeₓ compact with grains consolidated from nanoparticles of Bi₂Te₃₋ₓSeₓ is provided The grains have a grain size ranging from 20 to 100 nm, although larger grain sizes up to 1000 nm are suitable. The invention provides a combination of a structure with numerous grain boundaries for phonon scattering (to be discussed later) but with grain boundaries filled with the semiconductive Bi₂Te₃₋ₓSeₓ material to permit carrier conduction (to be discussed later).

The exemplary apparatus 24 includes two high strength pistons 26 and 28 that can apply a high compressive pressure, e.g., a pressure in a range of about 100 to about 2000 MPa, to a sample of nanoparticles, that is disposed within a high strength cylinder 30 while an optional current source 32 applies a current through the sample for heating thereof. In many embodiments, the current density is in a range of about 500 A/cm ² to about 3000 A/cm². The temperature of the sample (or an estimate thereof) can be obtained by measuring the temperature of the cylinder via an optical pyrometer (not shown) or a thermocouple attached to the sample surface. In one embodiment, the temporal duration of the applied pressure and current is preferably selected so as to compact and consolidate the nanoparticles. Apparatus 24 can be enclosed in an inert gas or oxygen free environment when compacting nanoparticles susceptible to oxygen degradation.

A compaction process for generating thermoelectric compacts provides a number of advantages. For example, this compaction process can provide a high yield (e.g., kilograms per day). Further, various reaction parameters, such as temperature, surfactant concentration and the type of solvent, can be readily adjusted to vary the size and morphology of the synthesized nanostructures.

To further elucidate the teachings of the invention and only for illustrative purposes, the synthesis of nanoparticles in accordance with various embodiments of the invention are described below. It should, however, be understood that the teachings of the invention can be utilized to synthesize other thermoelectric compacts besides those specifically called out below.

Materials Preparation: In one embodiment of this invention, elemental components (e.g. Bi, Se, and Te for Bi₂Te₃₋ₓSeₓ and Bi, Sb, and Te for BiₓSb₁₋ₓTe₃ with appropriate compositional weights) are formed into nanocrystalline alloy powders by either liquid nitrogen or room temperature high energy ball-milling of microscopic powders of these materials. Afterwards, the nanocrystalline alloy powders can be subjected to compaction in a high pressure hot-press, as described above for example.

FIG. 1A is a flowchart depicting the thermoelectric compact process of this invention, illustrated by way of example for production of a Bi₂Te₃₋ₓSeₓ n-type thermoelectric compact. At step 100, n-type nanocrystals of Bi₂Te₃₋ₓSeₓ were prepared by ball milling of the elemental powders at temperatures between 77K and room temperature. The grain sizes of the as-milled powders produced in this example were 8-13 nm. The milling process can be performed under a liquid nitrogen bath (instead of carrying out at room temperature) to help avoid agglomeration of the powder stock. At step 110, the milled thermoelectric powders are loaded in to a press. At step 120, the powders are consolidated at pressures of 100 MPa −2 GPa (depending on the type of powders being consolidated) and temperatures of 300 to 900° C. (depending on the type of powders being consolidated). In general, the compaction process provides enough consolidation to form workable substrate compacts without so much grain growth to remove the scattering sites from the bulk material. In one embodiment of this invention, the temperatures of 400 to 430° C. are ideal for the Bi₂Te₃-based nano-bulk materials. Further, the higher pressure compaction reduces the time of maintaining the process to fifteen minutes to 30 minutes, which reduces grain growth and keep the nanostructures in place. This is in contrast to prior sintering process commonly used by starting bulk thermoelectric compounds and crushing the bulk material s to nanopowders or starting with elemental powders and spark plasma sintering.

At step 130, the thermoelectric compact is removed from the press. After removal, the compact is sliced, polished, and cut into die for use in the thermoelectric elements of this invention.

The grain size of the Bi₂Te₃₋ₓSeₓ thermoelectric compacts after consolidation was observed to be as low as a few nm by transmission electron microscopy along with a range of grain sizes and some Te precipitates present. The thermoelectric properties of the Bi₂Te₃₋ₓSeₓ thermoelectric compacts were measured. Thermoelectric property data obtained for n-type Bi₂Te_{2.7}Se_{0.3} produced according to the invention by ball milling at 77 K to produce a nominal 10 nm powder of Bi₂Te_{2.7}Se_{0.3}, and compacting at 300° C. (lower power factor) versus ˜400° C. (higher power factor). In one embodiment of this invention, the power factor is increased by compaction at the higher temperature and higher pressures utilized in this invention.

More specifically, nanostructured thermoelectric n-type (Bi₂Te_{2.7}Se_{0.3}) and p-type (Bio₄Sb_{1.6}Te₃) material powders can be produced by one method of the invention involving high-energy ball milling and mechanical alloying. In this method, elemental powders, Bi, Te, Sb and Se (purity 99.99% or higher) supplied for example by Alfa Aesar, were weighed out in the appropriate atomic ratio and loaded into stainless steel vials with martensitic stainless steel balls under a high purity argon atmosphere (<1 ppm oxygen). The as-milled powders were then consolidated by uniaxial hot pressing carried out within an argon gas environment to avoid oxidation.

It is known that oxygen degrades the thermoelectric properties for Bi₂Te₃ based material. Accordingly, in one embodiment of the invention, an inert gas (or oxygen free gas) environment is provided during the milling or the hot-pressing. As a consequence, there is minimal oxidation at grain boundaries of the grains In one embodiment of the invention, there is less than 2% oxygen at grain boundaries of the grains. In one embodiment of the invention, there is less than 1% oxygen at grain boundaries of the grains. In one embodiment of the invention, there is less than 0.5% oxygen at grain boundaries of the grains. In one embodiment of the invention, there is less than 0.1% oxygen at grain boundaries of the grains.

The processing temperature and pressure are chosen for high relative density, small amount of grain growth, and no side reactions. In one embodiment, the compaction has been observed to occur for example at temperatures −407-417° C. at 2 GPa for n-type and −400-410° C. at 1.8 GPa for p-type materials, respectively. The total elevated temperature duration is typically limited to within 15 minutes to reduce the amount of grain growth. The resulting bulk disk samples (10 mm in diameter and about 800 microns in thickness) were polished for further characterizations.

While described above for thermoelectric materials, in this invention, other materials such as for example FeSb, FeSi, PbTe, PbSe, PbTeSe, GeTe, PbGeTe, PbSnTe, PbSnSe, PbS, PbSe, PbSSe, CdTe, CdMnTe, ZnTe, ZnSe, ZnSeTe, GaInAsSb, and GaInAsPSb are compounds whose bulk nano versions can be made by a combination of 77K ball milling using elemental components, followed by high-pressure compaction.

Consolidated bulk materials and nano-composite structure: In one embodiment of this invention, consolidated bulk disk samples have sufficient mechanical strength for handling and dicing for handling. In one aspect of this invention, bulk disk samples are consolidated from as-milled powders with small grain size (8˜24 nm) having the desired chemical composition. Specimens of the consolidated materials were prepared for transmission electron microscopy (TEM) by wedge polishing. Wedge specimens were then thinned for electron transparency with an ion mill and the sample stage cooled below −70° C. during the ion milling.

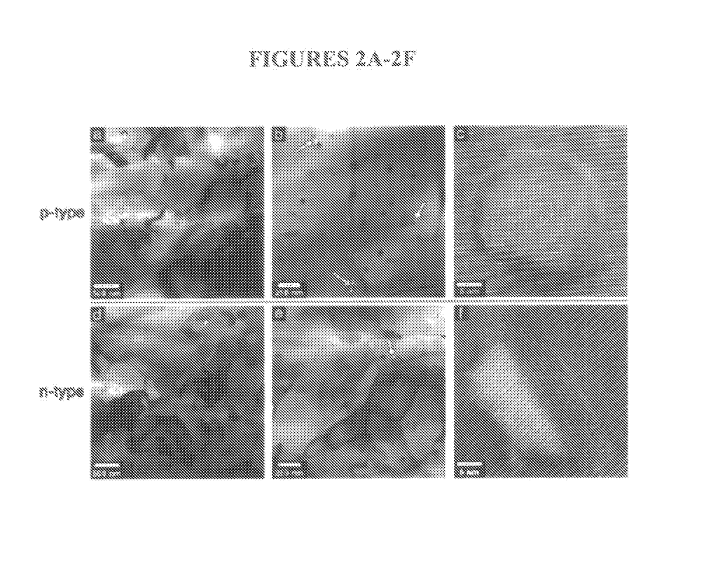

FIGS. 2A-2F shows representative bright-field TEM of p-type and n-type bulk consolidated samples under various magnification levels. In the case of the n-type consolidated sample (lower row), large grains, 0.5˜1 μm, were interspersed with small grains less than 150 nm in size. For the p-type consolidated samples sample (upper row), the majority of grains were observed to be in the range of 0.8˜1.3 μm, punctuated with small 200 nm grains. In one embodiment of this invention, the thermoelectric compacts are composed a first set of grains of a size from 0.5 to 5 microns and a second set of grains of a size ranging from 2-200 nm grains. Both types of materials (large and small grains) are closely packed with abrupt grain boundaries. Twin boundaries were also observed within the grains of both n- and p-type materials. In addition, small precipitates of about 6 to 15 nm in diameter are seen distributed throughout, see FIGS. 2B and 2E. Small precipitate formation was likely produced by the elevated temperatures of hot-pressing, while the high-energy ball milling produced the wide grain size distribution. In one embodiment of this invention, the small grains range from 2-100 nm, and the large grains range in size from 0.5 to 2 microns. In one embodiment of this invention, the small grains range from 5-50 nm, and the large grains range in size from 0.5 to 1 microns. In one embodiment of this invention, the small grains range from 5-10 nm, and the large grains range in size from 1 to 2 microns.

The absence of a strain field in these TEM micrographs indicates that the precipitates are incoherent with the surrounding matrix. FIG. 2C and 2F show HRTEM images of the n- and p-type material precipitates respectively, which confirms that the precipitates are incoherent and have a structure that differs from the matrix. Compositional analysis by EDS reveals one aspect of the invention where Sb-rich precipitates exist in the p-type material while there are no significant compositional differences seen in the precipitates observed in the n-type materials.

These precipitates are consistent with previously reported high-performance nanocrystalline p-type Bi₂Te₃ materials, but are inconsistent with commercial p- and n-type polycrystalline Bi₂Te₃ materials.

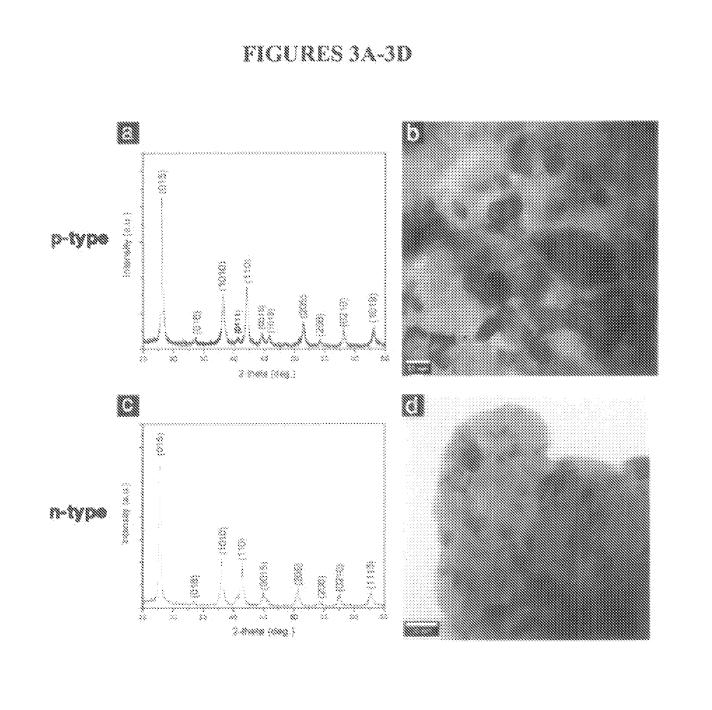

Grain size, material composition, and the presence of oxidation are factors in the starting nanocrystalline powders which affect the resultant compacts. FIG. 3A-3D are depictions of XRD spectrum (FIG. 3A and FIG. 3C) and transmission electron microscopy (TEM) (FIG. 3B and FIG. 3D) of an n- and a p-type as-milled powders. The observed peaks in XRD spectra well match the designed target composition and imply that the powders are single phase for both n and p type materials. The wide broadening of the peaks is due to their small grain size. The calculated average grain size of compounds within the powders, according to Scherrer's formula, is about 13 nm for n-type and 18 nm for p-type material which is further confirmed by the TEM images: the majority of the grains have size ranging 8-20 nm for n-type and 13-24 nm for p-type material. Those small size grains are evenly distributed in both type materials. The particle size of as-milled powders has a wide distribution from microns to nano scale. Some particles were observed to be less than 100 nm in the as milled powders.

Consolidated Bulk Disks and Commercial Materials

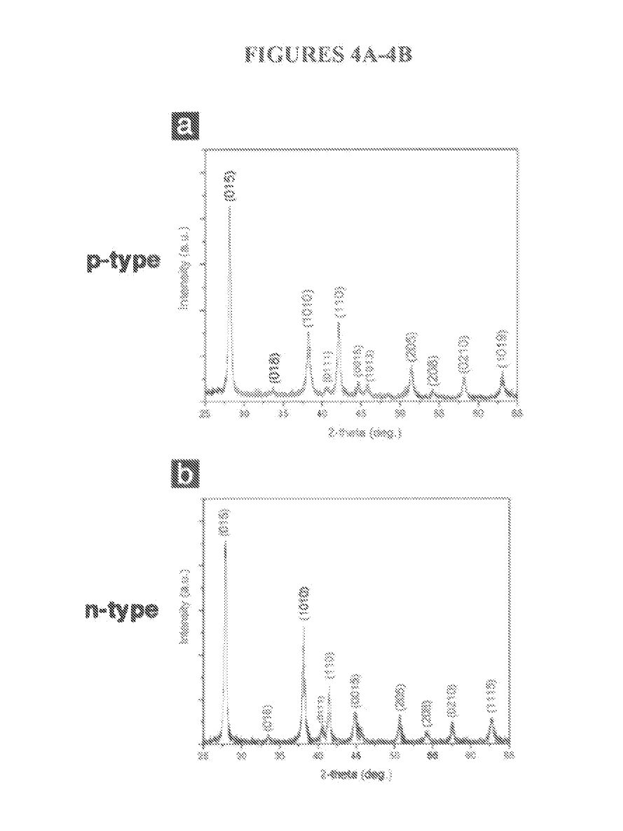

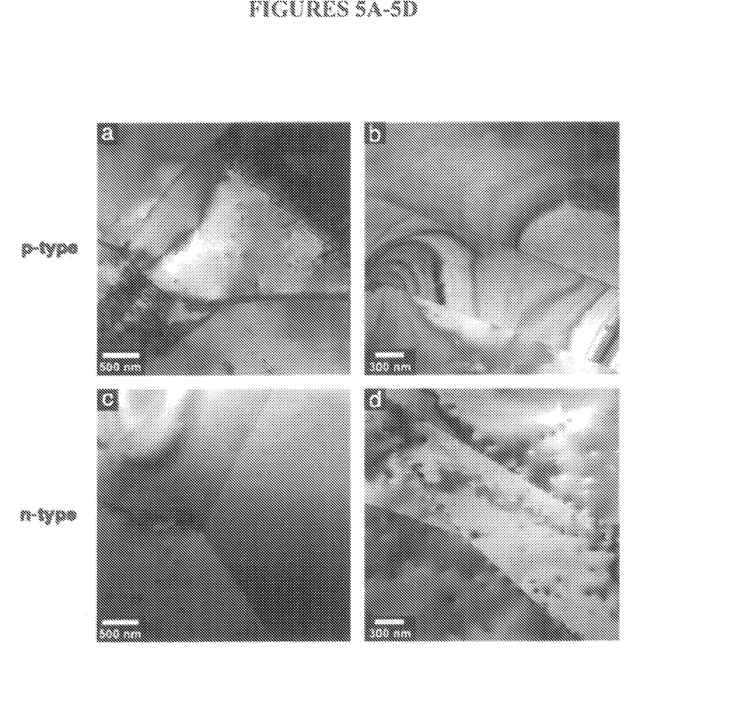

FIGS. 4A and 4B are depictions of XRD spectra of consolidated p-type and n-type bulk disks, respectively. From the XRD spectra, oxidation does not occur after the elevated temperature processing; all the peaks are identifiable with no visible peaks from second phases. For a comparison, TEM was performed on commercially available polycrystalline Bi₂Te₃ based TE materials with a JEOL 2000FX TEM. FIGS. 5A-5D are depictions of bright-field TEM micrographs of p-type and n-type bulk samples (conventionally made) under various magnification levels.

Several differences were observed. First, nanoscale precipitates were not observed in the commercial n-type bulk sample and only one precipitate (100 nm in size) was found in the commercial p-type bulk material TEM specimen. Second, the grain sizes of commercial Bi₂Te₃ were in the range of micrometers with a narrow size distribution. Third, the commercial materials exhibited dislocations throughout the grains and at grain boundaries. These differences in the presence of nano precipitates and large distributions of grain size in the compacts of this invention contribute to the enhanced ZT values and make the compacts of this invention a different material than that of the commercial materials in terms of microstructure.

In the compacts of this invention, nano-scale voids were sometimes observed at grain boundaries and precipitate-matrix interfaces. Those voids found at the grain boundaries likely originated from gaps between compacted powder particles that were not closed during the consolidation process. Voids located at precipitate-matrix interfaces indicate that some compositional fluctuation is present, likely the result of the mechanical alloying process. Off-stoichiometric compositions would induce the production of vacancies, and combined with the elevated temperatures of hot-pressing, produce agglomeration via diffusion. The observed total volume fraction of the voids is so miniscule that essentially both types of materials are consistent with the 99% or higher measured relative density. Similarly, the voids are not expected to have detrimental effects on mechanical stability of the materials, as evidenced by our ability to make devices and the high-performance device results.

Transport Properties:

The electrical resistivity of the Bi₂Te₃ nano-bulk materials were measured by the van der Pauw method in a Hall-effect set up that measured both electrical resistivity and carrier mobility/concentration at temperatures ranging from 25° C. to 125° C. The van der Pauw method, using four very small contacts (compared to the size of sample) symmetrically on the four corners of a typical square sample, ensures good measurement accuracy of the bulk electrical resistivity. The Seebeck coefficients were also measured between 25° C. to 125° C. as discussed in round-robin measurements. The thermal conductivity of nano-bulk samples between 25° C. to 125° C. were measured in the same direction as the electrical resistivity and the Seebeck coefficient, with measured heat flow using calibrated Q-meter. The thermal conductivities were calculated from Fourier law, given by the equation (1) below:

Q=k_{T}(α/l)ΔT (1)

where k_{T} is the average total (lattice plus electronic) thermal conductivity between temperatures Tₕₒₜ and T_{cold}, ΔT is the difference between Tₕₒₜ and T_{cold}, α is the cross-sectional area and l is the height of the thermoelectric pellet. The Q-meter measurements were calibrated with electric measurement of heat input, to within 5%.

The observed thermoelectric transport properties and ZT as a function of temperature from the Bi₂Te₃ compacts of this invention have been measured. For n-type material, the ZT peaks at about ˜2.4 around 125° C. This enhancement appears to be from the high Seebeck coefficient (˜320 μV/K) and a large reduction in lattice thermal conductivity (˜0.005 W/cm-K at 125° C.) compared to ˜0.01 W/cm-K in non-nano bulk materials.

While this invention is not limited to the following description, the following description is provided to permit better understanding of some of the physical properties of the compacts of the invention which can impact electrical and heat transport.

The Seebeck coefficient in the nano samples increased as temperature increased, while it was stable in the referenced non-nano materials to the measurement limit. Compared to n-type material with similar nano-structure and composition, the electrical resistivity values are in agreement ranging from 1×10⁻³ to 1.5×10⁻³ Ω-cm. The temperature dependence of the electrical resistivities of the various n-type samples suggests that the interface scattering of electrons is playing a larger role in nano materials. This is consistent with the expected interface density differences between nano and non-nano samples. While not limiting the invention, this scattering at “nano-sites” (e.g., voids, grain boundaries, precipitates, inclusions, etc) is likely playing a significant role in the observed higher Seebeck coefficient in the n-type nano-bulk material of this invention prepared by high-pressure compaction. In one aspect of this invention, the nano-sites have dimensions less than 20 nm. In one aspect of this invention, the nano-sites have dimensions less than 10 nm. In one aspect of this invention, the nano-sites have dimensions less than 5 nm. In one aspect of this invention, the nano-sites have dimensions between 2 and 5 nm. The thermal conductivity (k_{T}) is reduced 35% to around 1.1 W/m-K throughout the measurement temperature range as compared to data from bulk material. The temperature dependences of k_{L} of the two nano-compacts are different from the non-nano bulk material. Also, the resulting k_{L} is 0.0064 W/cm-K in nano materials in comparison to 0.0084 W/cm-K from non-nano material indicates the method and approach of the present invention can realize higher performance, approaching the theoretical and lowest observed value of −0.0025 W/cm-K in Bi₂Te₃-based nano-structures at RT.

The observed thermoelectric transport properties and ZT as a function of temperature for p-type material shows that ZT starts from ˜1.77 at room temperature, peaks at 50° C. with a value of ˜2.49, and peaking again at 100° C. to be ˜2.44 and then dropping back to 1.95. This complex observed variation in ZT is a result of the temperature dependence of various transport properties.

The observed ZT is almost double that of state-of-the-art BiₓSb₂₋ₓTe₃ alloy non-nano bulk and is about 40% higher than the best nanocomposite bulk p-type material with ZT-1.8. The observed enhancement in ZT in p-type samples appears to be from increased power factor resulting from the combination of high Seebeck coefficient (greater than 280 μV/K) at higher temperatures and low electrical resistivity (smaller than 1.2×10⁻³ Ω-cm) as well as modest reductions in k_{L} (0.004-0.007 W/cm-K) compared to non-nano materials (˜0.01W/cm-K).

The k_{L} in the nano p-type samples prepared by the high-pressure compaction of this invention is not as low as in nano p-type samples prepared by other methods. The temperature dependence of electrical resistivity of our high-pressure compacted nano-bulk is also significantly different from the other p-type nano samples. This suggests a smaller role of interface scattering of holes and is consistent with the higher l_{L} in the nano-bulk p-type prepared by high-pressure compaction of this invention. This temperature dependence of electrical resistivity is also reflected in the measured Seebeck coefficients. The Seebeck coefficients are significantly higher throughout the measurement range and consequently the power factor in this work is higher than that of conventional bulk non-nano-materials. This behavior in the p-type nano materials of the invention is strongly related to the presence and density of small precipitates/grains in the materials that play a role beyond lattice phonon scattering and lead to a different energy dependence of carrier scattering, hence leading to higher Seebeck coefficients and larger power factor.

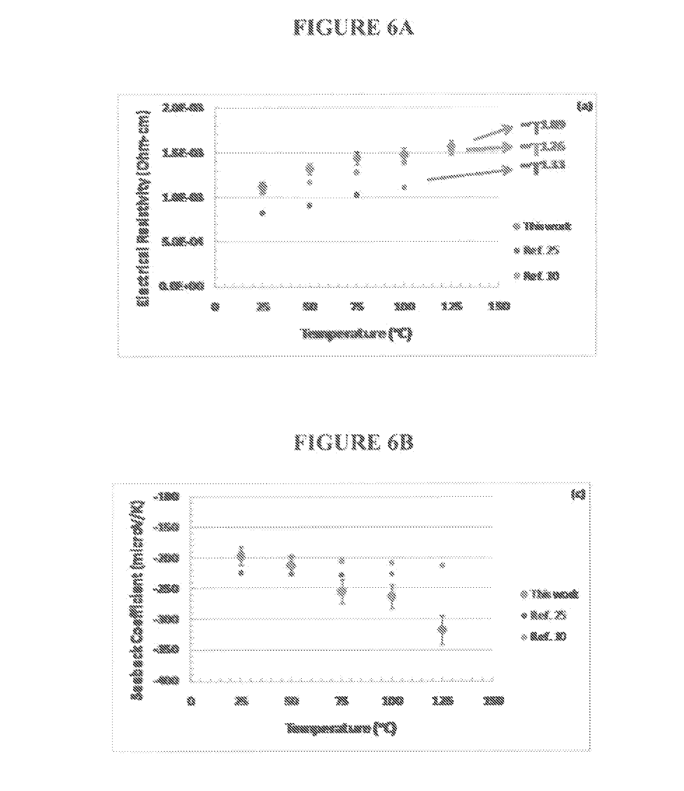

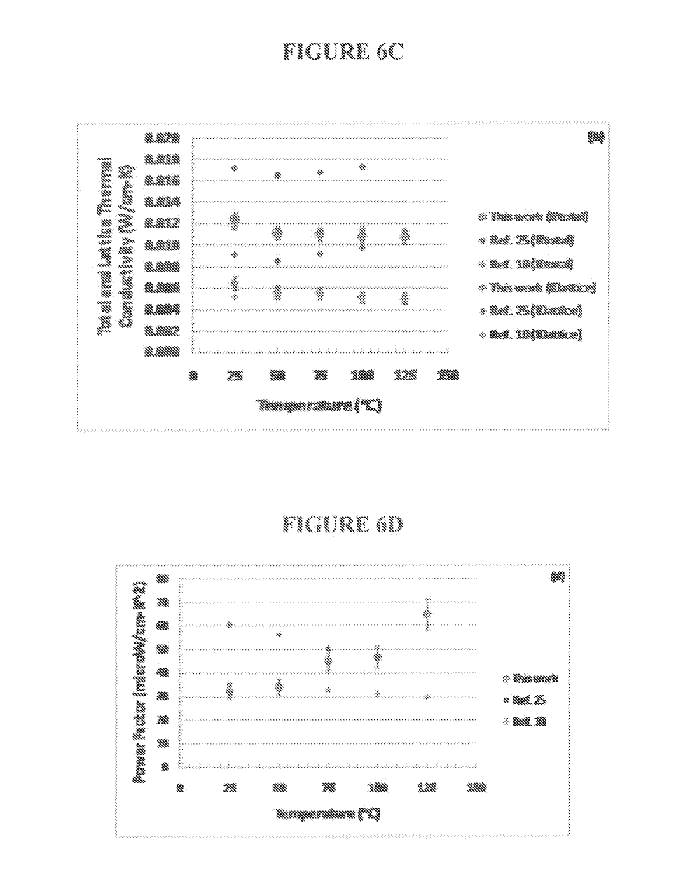

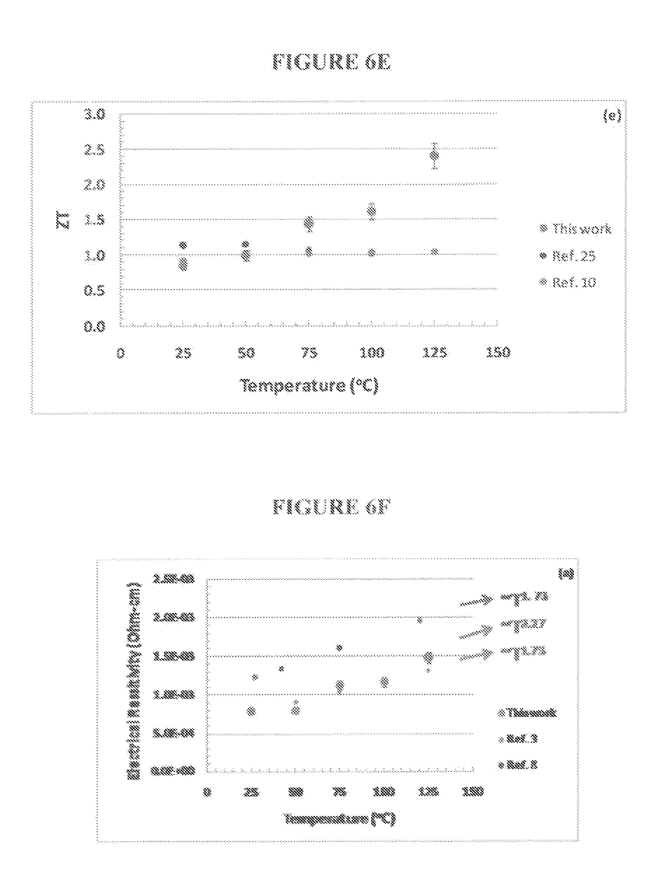

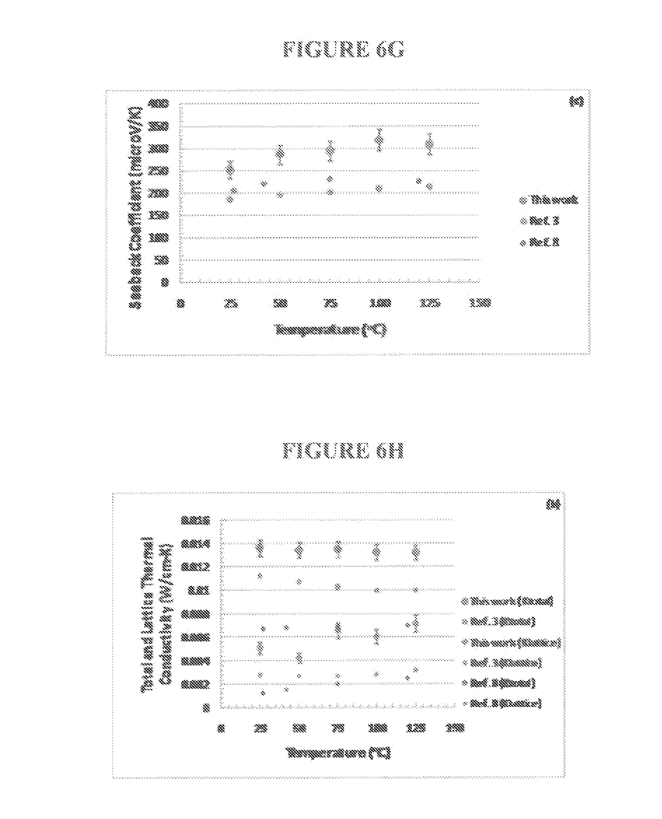

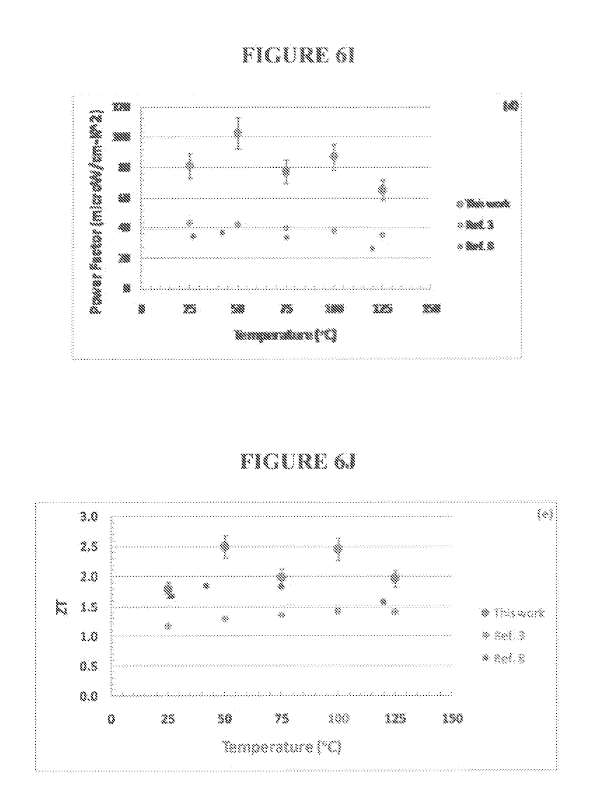

FIGS. 6A-6E are graphical depictions of the measured thermal properties of one of the n-type Bi₂Te_{2.7}Se_{0.3} thermoelectric compacts, as a function of temperature. FIGS. 6F-6J are graphical depictions of the measured thermal properties of one of the p-type Bi₂Te_{2.7}Se_{0.3} thermoelectric compacts, as a function of temperature. These graphical depictions show a trend of thermal conductivity reduction at lower temperature indicative of thermal conductivity dominated by nanostructures. These figures also show that the thermal conductivity of the n-type Bi₂Te_{2.7}Se_{0.3} thermoelectric compact is lower than that observed for a similar p-type Bi₂Te_{2.7}Se_{0.3} thermoelectric. The results are compared to published work: Ref 3—Poudel, B. et al. High-thermoelectric performance of nanostructured bismuth antimony telluride bulk alloys. Science 320, 634-638 (2008), Ref 8—Fan, S. et al. P-type Bi_{0.4}Sb_{1.6}Te₃ Nanocomposites with enhanced figure of merit. Appl. Phys. Lett. 96, 182104 (2010), Ref 10—Yan, X. et al. Experimental studies on anisotropic thermoelectric properties and structures of n-type Bi₂Te_{2.7}Se_{0.3}. Nano Lett. 10, 3373-3378 (2010), and Ref 25—Yamashita, O. & Sugihara, S. High-performance bismuth-telluride compounds with highly stable thermoelectric figure of merit. J. Mater. Sci, 40, 6439-6444 (2005).

Of importance in the results shown in FIGS. 6A-6E for the n-type material and for the results shown in FIGS. 6F-6J for the n-type material for the p-type material is the departures in performance metrics from even prior compact work where starting materials for the milling process were stoichiometric compounds of the semiconductors rather than the elemental powders themselves. U.S. Pat. Appl. Publ. No. 2008/0202575 to Ren et al entitled “Methods for High Figure of Merit in Nanostructured Thermoelectric Materials,” the entire contents of which are incorporated herein by reference, provides teachings therein related to various milling processes, various compaction processes, and alternative semiconducting thermoelectric materials although their techniques resulted in materials with degraded thermoelectric properties as compared to the elemental powder milling and limited time, high-pressure compaction processes described herein as also evidenced by material characteristics described next.

For the n-type material in FIG. 6A, the results show that in comparison to prior work the logarithmic slope (change in the logarithmic values of resistivity per ° C.) is less than 1.26/° C. and on the order of 1.09/° C., and thus ranging in the invention between 1.09 and 1.25/° C. For the n-type material in FIG. 6B, the results show that in comparison to prior work the magnitude of the Seebeck coefficient is remarkably increased at 125° C. to values at or above 300 μV/K, and thus ranging in the invention from 225 to 325 μV/K. For the n-type material in FIG. 6C, the results show that in comparison to prior work the total thermal conductivity is reduced from bulk values to 1.1 W/m-K at 125° C., and thus respectively ranging in the invention from 1.1 to 1.6 W/m-K at 125° C. For the n-type material in FIG. 6D, the results show that in comparison to prior work the power factor is increased to 60 W/cm-K² at 125° C., and thus respectively ranging in the invention from 45 to 60 W/cm-K² at 125° C.

For the p-type material in FIG. 6F, the results show that in comparison to prior work the logarithmic slope (change in the logarithmic values of resistivity per ° C.) is more than 1.73/° C. and on the order of 2.27/° C., and thus ranging in the invention between 1.75 and 2.27/° C. For the p-type material in FIG. 6G, the results show that in comparison to prior work the magnitude of the Seebeck coefficient is remarkably increased at 125° C. to values at or above 300 μV/K, and thus ranging in the invention from 250 to 325 μV/K. For the p-type material in FIG. 6H, the results show that in comparison to prior work the total thermal conductivity is reduced from bulk values to 1.35 W/m-K at 125° C., and thus respectively ranging in the invention from 1.0 to 1.35 W/m-K at 125° C. For the p-type material in FIG. 6I, the results show that in comparison to prior work the power factor is increased to 62 W/cm-K² at 125° C., and thus respectively ranging in the invention from 40 to 62 W/cm-K² at 125° C.

Furthermore, a high interface density helps reduce the mean free path of phonons and enhance phonon scattering. The increased interface density is contributed by small precipitates (<20 nm) along with several small grains ˜50 nm) observed in both n- and p-type materials, thus capable of scattering a range of phonon wavelengths. The high process temperature along with a short duration time allows the compaction to achieve high densification while limiting the amount of material diffusion and grain growth. Large grains are a tradeoff to obtain complete powder compaction that: 1) provides good electrical conductivity to maintain a high power factor, and 2) maintains sufficient mechanical strength for further sample processing of the brittle Bi₂Te₃. The reduced k_{L} may also result from structural defects introduced by ball milling: twin planes, dislocations and stacking faults etc. Although these low dimensional phonon scattering mechanisms are usually expected at a lower temperature range, it has been shown empirically to give contributions to thermal resistance around RT.

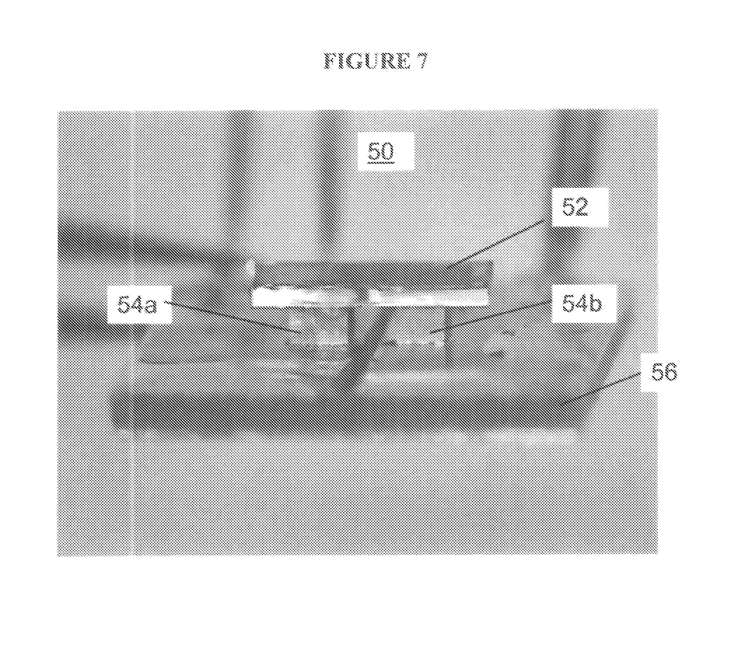

Device performance: FIG. 7 is a photographic depiction of a p-n thermoelectric device made with the thermoelectric composites described above.

FIG. 7 shows a thermoelectric device 50 in which a plate 52 bridges across an n-type thermoelectric element 54a (obtained from a compact) and a p-type thermoelectric element 54b (obtained from a compact). At opposite sides of the thermoelectric elements 54a and 54b, an electrical plate 56 for separately connecting to the thermoelectric elements 54a and 54b is provided. As a cooling device, current flow through the thermoelectric element 54a, the bridging plate 52, and the thermoelectric element 54b cools the bridging plate 52. As a power device, a temperature differential between the bridging plate 52 and the electrical plate 56 results in current flow or power production across a load connected (by way of the electrical plate 56) across thermoelectric elements 54a and 54b.

The power efficiency of the device depicted in FIG. 7 was found to represent a 20% improvement over a similar device made with conventional bulk Bi₂Te₃₋ₓSeₓ materials.

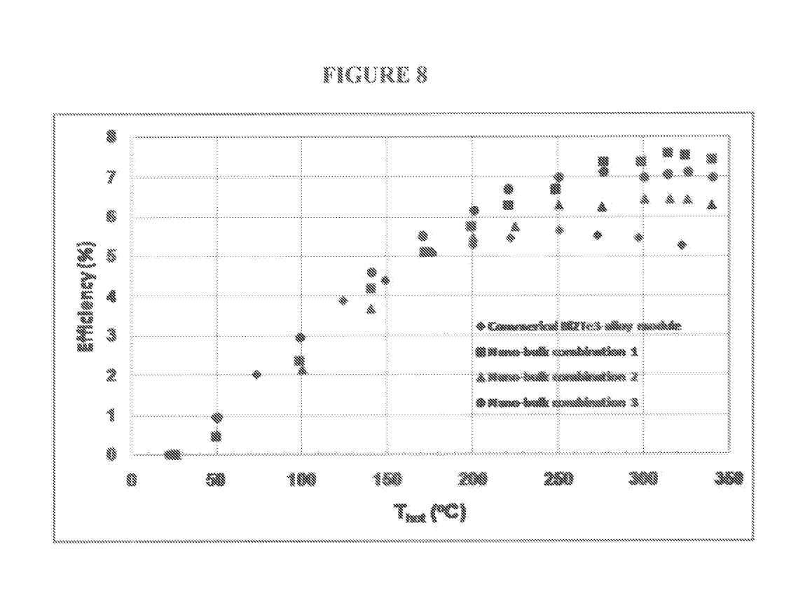

Heat-to-electric power generation devices were fabricated using n- and p-type nanostructured Bi₂Te₃-alloy materials of several combinations, for better p/n matching and also compared with non-nano commercial Bi₂Te₃-alloy bulk materials. The devices were power tested to determine the power output and efficiency that can be achieved with these new materials. FIG. 7 is a schematic depiction of measured heat-to-electric conversion efficiencies of n-p couples from commercial materials compared with the nano-structure compacts of this invention. Temperatures of the cold side and hot side of the device are measured at the same time that a maximum power point in current-voltage testing was measured. Efficiency at peak power was determined from measuring the heat flow (Q) through the device. Heat-to-electric conversion efficiency results for a nanostructured Bi₂Te₃-alloy couple and the reference non-nano commercial Bi₂Te₃-alloy bulk module, which is p/n matched, are shown in FIG. 8.

A maximum efficiency of 5.6% was achieved for a state-of-the-art commercial Bi₂Te₃-alloy bulk module at Tₕₒₜ=250° C., which was slightly higher than the efficiency of 5% obtained by comparison with a single p-n couple made with non-nano-bulk materials. With nanostructured Bi₂Te₃-alloy couples of this invention, device efficiency between 6.4% and 7.6% was achieved, depending on the p/n matching. In one embodiment of the invention, p-n matching and other factors like compatibility factor over a rather large temperature range, by tuning the nano materials' transport parameters, can improve the 7.6% efficiency considerably. Even so, the efficiency of 7.6% represents a 36% improvement over best commercial Bi₂Te₃-alloy bulk module. The nano-material couples realized by this invention have an efficiency peaking at higher temperatures as well, around 300° C., consistent with higher Seebeck coefficients in both n- and p-type materials. This heat-to-electric power conversion thermoelectric device, made of such nano-composite p- and n-type materials, have a heat-to-electric conversion efficiency of as much as 6.5 to 7.6% which is much greater than typical efficiencies of 5% for devices made with non-nano-bulk materials. Refinements of the temperature-dependent properties of the p-type and n-type materials, between 25° C. and 300° C., permit, in one embodiment, heat-to-electric conversion efficiencies equal to or greater than 10%

In one embodiment of the invention, the higher temperature performance is conducive for applications in exhaust automotive waste-heat recovery. This invention permits for a wide application of nanostructured Bi₂Te₃-alloy materials for efficient power conversion and energy harvesting devices.

In one aspect of the invention, the concentration of Te and Se in the Bi₂Te₃₋ₓSeₓ composites can vary from all Te to all Se. In one aspect of the invention, the Bi₂Te₃₋ₓSeₓ composites can be n-type. In one aspect of the invention, the Bi₂Te₃₋ₓSeₓ composites can be p-type. Accordingly, thermoelectric devices can be fabricated to provide for devices with higher performance than devices fabricated from bulk Bi₂Te₃₋ₓSeₓ materials.

In another embodiment of the invention, the particle size in the thermoelectric compacts can range from about a few nanometers to about 5000 nanometers (e.g., in a range of about 500 nm to about 5000 nm or in a range of about 500 nm to about 1000 nm for the larger size grains; and in a range of about 10 nm to about 200 nm or in a range of about 5 nm to about 100 nm for the smaller size grains). In another embodiment of the invention, the particle size in the thermoelectric compacts can be less bifurcated such that more of an average grain size persists throughout the material.

Accordingly, the present invention provides nano-composites of both n-type Bi₂Te_{2.7}Se_{0.3} and p-type Bi_{0.4}Sb_{1.6}Te₃ alloy thermoelectric materials with significantly enhanced figure of merit (ZT) between 25° C. and 125° C. Using an optimized high-pressure compaction process, the present invention provides for a drastic enhancement in ZT for bulk n- and p-type materials, with ZT values as high as 2.4 obtained around 125° C., thus allowing us to break through the ZT>2 barrier in bulk thermoelectric materials. By incorporating a high concentration of nanoscale structures, a significant improvement of the Seebeck coefficient is provided while reducing lattice thermal conductivity as well. As proof of the significance of these improves material properties, heat-to-electric power device utilizing the novel material compacts have shown a nearly 40% improvement over previous state-of-the-art devices. The material and device results reported in this study therefore represent an important transition of nanobulk thermoelectric-materials to device technology for a wide range of power generation and efficient waste heat recovery applications. For example, a device conversion efficiency of 7.6% should lead to a relative improvement of 5% in fuel-efficiency, an important threshold, in automotive waste heat recovery.

With this invention, efficient devices utilizing bulk nano-materials are possible permitting the realization of novel devices such as for example heat-to-electric conversion devices, thermoelectric cooling devices, solar-thermal system devices, and waste-heat harvesting devices. Indeed, high-pressure compacted nano-powders of this invention have shown both enhanced power factor and reduced lattice thermal conductivity, thereby achieving a ZT˜2.4 for both n- and p-type materials near 125° C. Furthermore, heat-to-electric power conversion efficiency of about 7.6% have been realized, a 36% improvement in device efficiency compared to devices made from conventional or state-of-the-art Bi₂Te₃-alloy materials (5.6% conversion efficiency). Thus, this invention establishes for the first time the device advantage of nano materials for power generation applications such as harnessing automotive waste heat and in solar thermal systems.

Numerous modifications and variations of the invention are possible in light of the above teachings. It is therefore to be understood that within the scope of the appended claims, the invention may be practiced otherwise than as specifically described herein.

1. A thermoelectric composite, comprising:
a semiconductor material formed from mechanically-alloyed powders of elemental constituents of the semiconductor material to produce nanoparticles of the semiconductor material, and compacted to have at least a bifurcated grain structure; and
said bifurcated grain structure having at least two different grain sizes including small size grains in a range of 2-200 nm and large size grains in a range of 0.5 to 5 microns.

2. The composite of claim 1, wherein the semiconductor material has a figure of merit ZT, defined as a ratio of the product of square of Seebeck coefficient S and electrical conductivity σ divided by the thermal conductivity k, which varies from greater than 1 at 300 K to 2.5 at temperatures of 300 to 500K.

3. The composite of claim 1, wherein the semiconductor material comprises nano-size scattering sites including at least one of nano-voids, inclusions, precipitates, and grain boundaries.

4. The composite of claim 1, wherein the semiconductor material comprises nano-size scattering sites having dimensions less than 10 nm.

5. The composite of claim 1, wherein the semiconductor material comprises nano-size scattering sites having dimensions less than 5 nm.

6-12. (canceled)

13. The composite of claim 1, wherein the small size grains have a grain size ranging from 2 to 50 nm.

14. The composite of claim 1, wherein said compact comprises at least one of n-type Bi₂Te₃₋ₓSeₓ and p-type B_{y}Sb_{2-y}Te₃.

15. The composite of claim 14, wherein x ranges from 0.1 to 0.9 and y ranges from 0.1 to 0.9.

16. The composite of claim 14, wherein x ranges from 0.2 to 0.5 and y ranges from 0.2 to 0.6.

17. The composite of claim 14, wherein x ranges from 0.25 to 0.35 and y ranges from 0.35 to 0.45.

18-19. (canceled)

20. The composite of claim 1, wherein said semiconductor material comprises n-type Bi₂Te₃₋ₓSeₓ and has at least one of the following properties:
a logarithmic slope of resistivity ranging from 1.09 to 1.25/° C.;
a Seebeck coefficient at 125° C. ranging from 225 to 325 μv/K;
a thermal conductivity at 125° C. ranging from 1.1 to 1.6 W/m-K; and
a power factor at 125° C. ranging from 45 to 100 micro W/cm-K.

21-45. (canceled)

46. The composite of claim 1, wherein said semiconductor material comprises p-type Bi_{y}Sb_{2-y}Te₃ and has at least one of the following properties:
a logarithmic slope of resistivity ranging from 1.75 to 2.27/° C.;
a Seebeck coefficient at 125° C. ranging from 250 to 325 μ\7K;
a thermal conductivity at 125° C. ranging from 1.0 to 1.35 W/m-K; and
a power factor at 125° C. ranging from 40 to 100 micro W/cm-K².

47. A thermoelectric device, comprising:
an n-type compacted thermoelectric element having at least a bifurcated grain structure with at least two different grain sizes including small size grains in a range of 2-200 nm and large size grains in a range of 0.5 to 5 microns; and
a p-type compacted thermoelectric element having at least a bifurcated grain structure with at least two different grain sizes including small size grains in a range of 2-200 nm and large size grains in a range of 0.5 to 5 microns.

48. The device of claim 47, wherein:
the n-type compacted thermoelectric element comprises a n-type Bi₂Te₃₋ₓSeₓ section having grains consolidated from nanoparticles of Bi₂Te₃₋ₓSeₓ; and
the p-type compacted thermoelectric element comprises a p-type Bi_{y}Sb_{2-y}Te₃ section having grains consolidated from nanoparticles of p-type Bi_{y}Sb_{2-y}Te₃.

49. The device of claim 47, wherein said grain size of the n-type Bi₂Te₃₋ₓSeₓ section or the p-type Bi_{y}Sb_{2-y}Te₃ section ranges from 30 to 50 nm.

50. The device of claim 47, wherein said grain size of the n-type Bi₂Te₃₋ₓSeₓ section or the p-type Bi_{y}Sb₂₋ₓTe₃ section averages 40 nm.

51. A compacted composite, comprising:
a material formed from mechanically-alloyed powders of elemental constituents of the semiconductor material to produce nanoparticles of the semiconductor material, and compacted to have at least a bifurcated grain structure; and
said bifurcated grain structure having at least two different grain sizes including small size grains in a range of 2-200 nm and large size grains in a range of 0.5 to 5 microns.
